(19) United States
(12) Patent Application Publication
(10) Pub. No.: US 2013/0312940 A1
(43) Pub. Date: Nov. 28, 2013

(54) HEAT DISSIPATING DEVICE AND SYSTEM

(71) Applicant: Celestica Technology Consultancy (Shanghai) Co., Ltd., Shanghai (CN)

(72) Inventor: Jen Chieh HUANG, New Taipei City (TW)

(73) Assignee: Celestica Technology Consultancy (Shanghai) Co., Ltd., Shanghai (CN)

(21) Appl. No.: 13/899,680

(22) Filed: May 22, 2013

(30) Foreign Application Priority Data
May 28, 2012 (TW) 101210143

(51) Int. Cl. H05K 7/20

(52) U.S. Cl. CPC H05K 7/20145
USPC 165/104.34

(57) ABSTRACT

A heat dissipating device disposed on a heat source and in a flow channel is disclosed. The heat dissipating device includes a first fin set, a second fin set, and a baffle. The first fin set is disposed at an entrance of the flow channel, and the second fin set is disposed at an exit of the flow channel. The baffle is disposed between the first fin set and the second fin set, and divides the flow channel into a first flow channel and a second flow channel. The sectional area of the entrance of the first flow channel is larger than that of the exit of the first flow channel. The sectional area of the entrance of the second flow channel is smaller than that of the exit of the second flow channel.

This application claims priority to Taiwanese Patent Application No. 101210143 filed on May 28, 2012.

### BACKGROUND

Generally speaking, in addition to the indispensable components such as a central processing unit (CPU), a main board and a hard disk, large-scale data processing devices, such as desktop computers, laptops, tablet computers or household game machines, still require various hardware components to improve data processing capability. However, such hardware components give off heat during operations. The heat generated by the hardware components must be dissipated out of the data processing devices effectively, otherwise the increase of temperature within the housings of the data processing devices would adversely affect the operation of the data processing devices or, even worse, permanently damage the data processing devices.

A conventional approach to dissipate heat from a large-scale data processing device is to dissipate heat out of the data processing device through a convection air flow produced by a fan and a heat dissipating hole set on the housing. However, due to some hardware components that generate lots of heat (e.g., a CPU), the convention air flow may not be enough to lower the temperature down to a normal range. Therefore, an extra fan or other auxiliary heat dissipating elements (e.g., fins) may be provided to facilitate heat dissipation. The fins disposed on the hardware components can increase the contact area of the hardware components and the air flow so that more heat can be conducted to the air flow.

Although the increased contact area of the hardware component and the air flow can conduct more heat to the air flow, however, the effect is limited. For example, if an air flow moves from a front fin to a rear fin, the air flow carries most of heat of the front fin when passing the front fin; however, the air flow may not efficiently carry the heat of the rear fin when passing the rear fin. In other words, the heat dissipating efficiency depends on the positions on the hardware component. Even if the heat dissipation efficiency is high in a certain area of the hardware component, the hardware component is still likely to be affected or even permanently damaged if heat cannot be dissipated effectively from other areas of the hardware component.

Conventional solution to solve the aforesaid problem is to change the height of the fins. Referring to FIG. 1, which is a schematic diagram illustrating fins 12 disposed on a heat source 10 in the prior art. As shown in FIG. 1, the fins 12 on the heat source 10 may be divided into first fins 120 and second fins 122. An air flow produced by a fan 14 flows from the first fins 120 towards the second fins 122. As the second fins 122 have a height greater than that of the first fins 120, an upper portion of the air flow does not pass through the first fins 120 but flows to an upper portion of the second fins 122 directly to carry away heat thereof. In this way, the heat dissipating efficiency of the second fins 122 is improved. However, the increased height of the second fins 122 is adverse to a compact design concept of electronic devices nowadays.

It may therefore be desirable to design a new heat dissipating device that can facilitate heat dissipation but occupies a small space.

### BRIEF SUMMARY

The subject application generally relates to a heat dissipating device and a heat dissipating system and, more particularly, to a heat dissipating device and a heat dissipating system that can assist in evenly dissipating heat from a heat source.

An objective of the present invention is to provide a heat dissipating device to solve the problem in the prior art.

According to an embodiment, examples of the present invention may provide a heat dissipating device disposed on a heat source and in a flow channel, and the heat dissipating device comprises a first fin set, a second fin set and a baffle. The first fin set is disposed at an entrance of the flow channel and comprises a plurality of first fins; the second fin set is disposed at an exit of the flow channel and comprises a plurality of second fins, wherein a part of the second fins are disposed at positions corresponding to a part of the first fins. The baffle is disposed between the first fin set and the second fin set to divide the flow channel into a first flow channel and a second flow channel parallel to each other. An entrance of the first flow channel has a sectional area larger than that of an exit of the first flow channel, and an entrance of the second flow channel has a sectional area smaller than that of an exit of the second flow channel.

Another objective of the present invention is to provide a heat dissipating system to solve the problem in the prior art.

According to another embodiment, some examples of the present invention may provide a heat dissipating system to dissipate heat from a heat source, and the heat dissipating system comprises a flow channel and a heat dissipating device that are disposed on the heat source. The heat dissipating device is disposed in the flow channel, and comprises a first fin set, a second fin set and a baffle. The first fin set is disposed at an entrance of the flow channel and comprises a plurality of first fins; the second fin set is disposed at an exit of the flow channel and comprises a plurality of second fins, wherein a part of the second fins are disposed at positions corresponding to a part of the first fins. The baffle is disposed between the first fin set and the second fin set to divide the flow channel into a first flow channel and a second flow channel parallel to each other. An entrance of the first flow channel has a sectional area larger than that of an exit of the first flow channel, and an entrance of the second flow channel has a sectional area smaller than that of an exit of the second flow channel.

Still other examples of the present invention may provide a heat dissipating system to dissipate heat from a heat source in an electronic device, the heat dissipating system comprises a flow channel disposed on the heat source; at least one fan to determine a direction of an air flow in the flow channel; and a heat dissipating device disposed in the flow channel and on the heat source, the heat dissipating device comprises a first fin set disposed at an entrance of the flow channel and comprising a plurality of first fins; a second fin set disposed at an exit of the flow channel and comprising a plurality of second fins, wherein a part of the second fins are disposed at positions corresponding to a part of the first fins; and a baffle disposed between the first fin set and the second fin set to divide the flow channel into a first flow channel and a second flow channel parallel to each other, wherein the air flow passes through the heat dissipating device and carries away the heat on the first fin set and the second fin set.

Advantages and spirits of the present invention will be further understood by reviewing the following detailed descriptions with reference to the attached drawings.

Additional features and advantages of the present invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The foregoing summary, as well as the following detailed description of the invention, will be better understood when read in conjunction with the appended drawings. For the purpose of illustrating the invention, there are shown in the drawings examples which are presently preferred. It should be understood, however, that the invention is not limited to the precise arrangements and instrumentalities shown.

In the drawings:

FIG. 1 is a schematic diagram illustrating fins disposed on a heat source in the prior art;

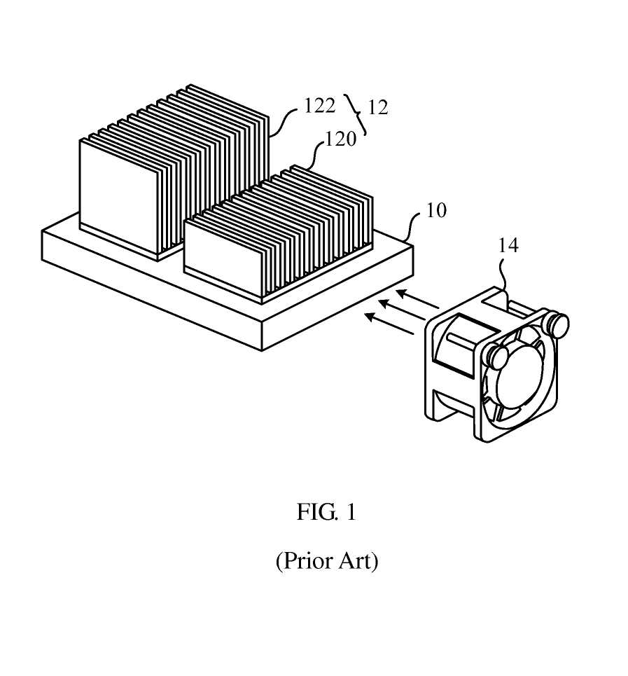

FIG. 2A is a schematic diagram of a heat dissipating system in accordance with an embodiment of the present invention;

FIG. 2B is a top view of the heat dissipating system of FIG. 2A; and

FIG. 3 is a schematic diagram of a heat dissipating system in accordance with another embodiment of the present invention.

### DETAILED DESCRIPTION OF THE INVENTION

The present invention can be understood more easily and clearly by referring to the following DETAILED DESCRIPTION OF THE INVENTION and examples comprised therein. Only necessary elements of the present invention are elucidated in this specification, and the two sections BRIEF SUMMARY OF THE INVENTION and DETAILED DESCRIPTION OF THE INVENTION of this specification are only intended to illustrate one of possible examples of the present invention. However, the scope of the technical essence claimed by the present invention shall not be limited by the description of this specification. Unless explicitly excluded in this specification, the present invention is not limited to a specific structure, material, function or means. It shall also be appreciated that, what described herein are only possible embodiments of the present invention, and any methods, materials, elements, devices or means similar or equivalent to the methods and the materials described in this specification may be used in practices or tests of the present invention. Moreover, the attached drawings are only intended to express the spirits of the present invention, the scale of the structure depicted in the attached drawings is only for reference, and users can freely enlarge or reduce the scale of individual structural elements according to the common knowledge in the art so as to achieve the efficacy described in this specification.

Furthermore, unless otherwise defined, all technical and scientific terms used in this specification have the same meanings as those usually appreciated by people skilled in the art. Although any methods and materials similar or equivalent to the methods and the materials described in this specification may be used in practices or tests of the present invention, what described herein are exemplary methods and materials which are only for reference.

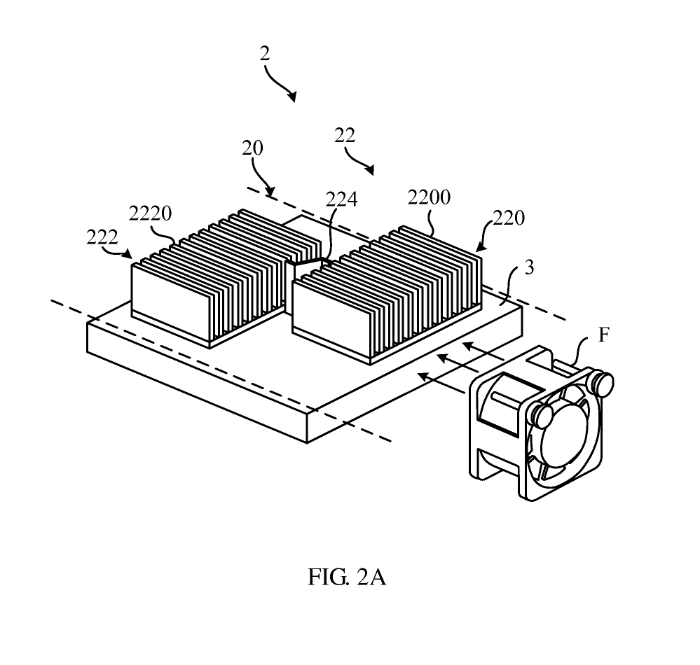

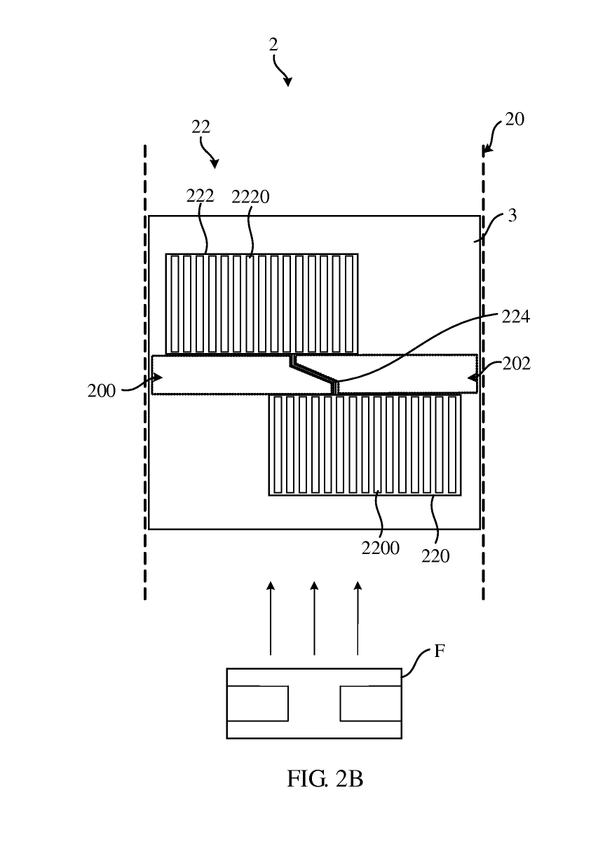

Referring to FIG. 2A and FIG. 2B, FIG. 2A is a schematic diagram of a heat dissipating system 2 in accordance with an embodiment of the present invention, and FIG. 2B is a top view of the heat dissipating system 2 of FIG. 2A. The heat dissipating system 2 of this embodiment is used to assist in dissipating heat from a heat source 3. In practice, the heat dissipating system 2 can be used in a data processing device or some other electronic apparatus with a component generating massive heat. For example, the heat dissipating system 2 may be installed in a housing of a desktop computer or a projector to assist in dissipating heat from hardware components such as a central processing unit (CPU) or a luminous source. As shown in FIG. 2A and FIG. 2B, the heat dissipating system 2 cooperates with a fan F to assist in dissipating heat from the heat source 3, and the heat dissipating system 2 may comprise a flow channel 20 and a heat dissipating device 22 that is disposed on the heat source 3.

In this embodiment, the range of the flow channel 20 is defined by the range of an air flow; however, the air flow channel may also be defined by a physical partition in practice, and the present invention has no limitation on this. The air flow generated from the fan F passes through the flow channel 20 and then exits via an air vent or a heat outlet on the housing.

The heat dissipating device 22 is disposed on the heat source 3, and comprises a first fin set 220 and a second fin set 222 which are disposed at an entrance and an exit of the flow channel 20 respectively. In other words, the air flow entering into the flow channel 20 passes through the position of the first fin set 220 firstly and then passes through the position of the second fin set 222. The first fin set 220 further comprises a plurality of first fins 2200 arranged in parallel with the flow channel 20. Likewise, the second fin set 222 further comprises a plurality of second fins 2220 arranged in parallel with the flow channel 20. As shown in FIG. 2A and FIG. 2B, the first fin set 220 and the second fin set 222 are arranged alternately, and a part of the second fins 2220 are disposed at positions corresponding to a part of the first fins 2200.

In addition to the first fin set 220 and the second fin set 222, the heat dissipating device 22 further comprises a baffle 224 which is disposed between the first fin set 220 and the second fin set 222. As shown in FIG. 2A and FIG. 2B, the baffle 224 is inclined with respect to the direction of the flow channel 20, and further divides the flow channel 20 into a first flow channel 200 and a second flow channel 202. In this embodiment, an entrance of the first flow channel 200 has a sectional area larger than that of an exit of the first flow channel 200, and an entrance of the second flow channel 202 has a sectional area smaller than that of an exit of the second flow channel 202. It shall be noted that, the entrances and the exits of the first flow channel 200 and the second flow channel 202 are determined by the direction of the air flow; that is, the air flow enters into the entrances of the first flow channel 200 and the second flow channel 202 and exits from the exits of the first flow channel 200 and the second flow channel 202.

When the air flow enters into the flow channel 20, a part of the air flow passes through each of the first fins 2200 of the first fin set 220 and carries away the heat on each of the first fins 2200. Then, the air flow is guided by the baffle 224 into the first flow channel 200 and the second flow channel 202 respectively and flows into the second fin set 222 via the exits of the first flow channel 200 and the second flow channel 202. The air flow passes through each of the second fins 2220 of the second fin set 222 and carries away the heat on each of the second fins 2220.

As shown in FIG. 2A and FIG. 2B, the first fin set 220 and the second fin set 222 are arranged alternately, and the baffle 224 divides the flow channel 20 into the first flow channel 200 and the second flow channel 202. Therefore, after the air flow passes through the first fin set 220, the temperature of the entire air flow will not be increased all at once. Then, the first flow channel 200 and the second flow channel 202 distribute the air entering into the second fin set 222 in such a way that the air passing through the second fin set 222 still keeps a high heat-carrying capacity. Through the design of this embodiment, both the first fin set 220 and the second fin set 222 have a good heat dissipating efficiency and can dissipate heat from the heat source 3 evenly.

It shall be noted that, in this embodiment, each of the first fins 2200 of the first fin set 220 have a height substantially the same as that of each of the second fins 2220 of the second fin set 222. As the first fin set 220 and the second fin set 222 are arranged alternately and the baffle 224 divides the flow channel 20 to distribute the air flow, the heat-carrying capacity of the air flow entering into the second fin set 222 will not be significantly reduced. Therefore, it is unnecessary to additionally increase the height of the second fins 2220, and this is favorable for miniaturization of electronic devices.

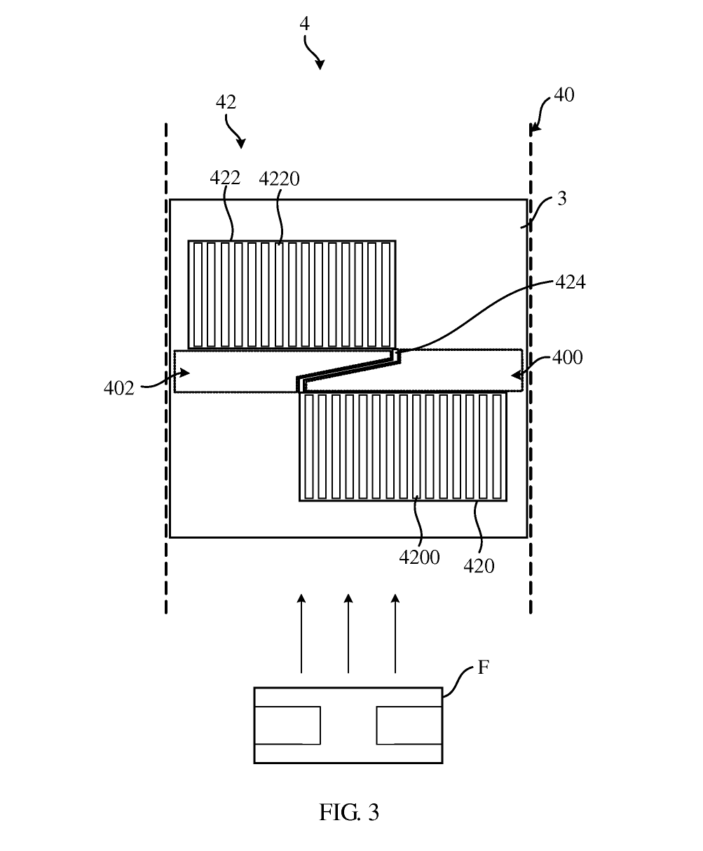

Referring to FIG. 3, FIG. 3 is a schematic diagram of a heat dissipating system 4 in accordance with another embodiment of the present invention. As shown in FIG. 3, the heat dissipating system 4 of this embodiment is also used to assist in dissipating heat from a heat source 3 in a data processing device or some other electronic apparatus with a component generating massive heat. This embodiment differs from the aforesaid embodiment in that, a baffle 424 of a heat dissipating device 42 of this embodiment is inclined at a different angle with respect to a flow channel 40. In detail, a first flow channel 400 and a second flow channel 402 divided by the baffle 424 are at positions opposite to those of the first flow channel and the second flow channel of the previous embodiment. It shall be noted that, other units (e.g., a first fin set 420 or a second fin set 422) of the heat dissipating system 4 of this embodiment are substantially the same as those of the previous embodiment, and thus will not be further described herein.

In this embodiment, an entrance of the first flow channel 400 has a sectional area larger than that of an exit of the first flow channel 400, and an entrance of the second flow channel 402 has a sectional area smaller than that of an exit of the second flow channel 402. The entrances and the exits of the first flow channel 400 and the second flow channel 402 are also determined by the direction of the air flow, and this has been described above and thus will not be further described herein. The entrance of the first flow channel 400 is connected to the first fin set 420, and the exit of the second flow channel 402 is connected to the second fin set 422. Through division of the flow channel 40 by the baffle 424, the parts of the air flow obtained by the first fin set 420 and the second fin set 422 can have the same heat-carrying capacity so that the first fin set 420 and the second fin set 422 have substantially the same heat dissipating efficiency.

As shown in FIG. 3, when the air flow enters into the flow channel 40, a part of the air flow passes through each of the first fins 4200 of the first fin set 420 and carries away the heat on each of the first fins 4200. Then, the air flow carrying the heat conducted from the first fin set 420 is guided by the baffle 424 into the first flow channel 400; and after exiting from the first flow channel 400, the air flow passes through a side of the second fin set 422 and exits via an air vent or a heat outlet on the housing. On the other hand, the other part of the air flow entering into the flow channel 40 passes through a side of the first fin set 420. Next, the air flow is guided by the baffle 424 into the second flow channel 402 and enters into the second fin set 422 via the exit of the second flow channel 402. Then, the air flow carries away the heat on each of the second fins 4220 of the second fin set 422 and exits via the air vent or the heat outlet. In this embodiment, the air flow passing through the second fin set 422 passes through the side of the first fin set 420, so the heat-carrying capacity of the air flow when entering into the flow channel 40 can be maintained. As the baffle divides the flow channel 40 into the first flow channel 400 and the second flow channel 402, the parts of the air flow entering into the first fin set 420 and the second fin set 422 can have the same heat-carrying capacity (i.e., the first fin set 420 and the second fin set 422 have the same heat dissipating efficiency) so that the heat can be dissipated from the heat source 3 evenly without the need of increasing the height of each of the second fins 4220 of the second fin set 422.

According to the above descriptions, the heat dissipating system of the present invention has a flow channel and a heat dissipating device disposed on the heat source, and the heat dissipating device comprises a first fin set and a second fin set disposed at an entrance and an exit of the flow channel respectively to assist in dissipating heat from the heat source. Furthermore, the heat dissipating device further has a baffle, which is disposed between the first fin set and the second fin set to divide the flow channel into a first flow channel and a second flow channel to distribute the air flow entering into the flow channel in such a way that parts of the air flow passing through the first fin set and the second fin set have the same heat-carrying capacity (i.e., the first fin set and the second fin set have the same heat dissipating efficiency). Furthermore, because the parts of the air flow passing through the first fin set and the second fin set have the same heat-carrying capacity, it is unnecessary to additionally increase the height of each of the second fins of the second fin set and this is favorable for miniaturization of modern electronic devices.

The detailed description of the above preferred embodiments is intended to describe the features and spirits of the present invention more clearly, but is not to limit the scope of the present invention. Rather, the objective of the detailed description of these preferred embodiments is intended to cover various modifications and equivalent arrangements within the scope claimed by the present invention.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

We claim:

1. A heat dissipating device disposed in a flow channel and on a heat source, the heat dissipating device comprising:
a first fin set disposed at an entrance of the flow channel and comprising a plurality of first fins;
a second fin set disposed at an exit of the flow channel and comprising a plurality of second fins, wherein a part of the second fins are disposed at positions corresponding to a part of the first fins; and
a baffle disposed between the first fin set and the second fin set to divide the flow channel into a first flow channel and a second flow channel parallel to each other,
wherein an entrance of the first flow channel has a sectional area larger than that of an exit of the first flow channel, and an entrance of the second flow channel has a sectional area smaller than that of an exit of the second flow channel.

2. The heat dissipating device of claim 1, wherein the first fins have a height the same as that of the second fins.

3. The heat dissipating device of claim 1, wherein the entrance of the first flow channel communicates with the first fin set.

4. The heat dissipating device of claim 1, wherein the exit of the second flow channel communicates with the second fin set.

5. A heat dissipating system for dissipating heat from a heat source, the heat dissipating system comprising:
a flow channel disposed on the heat source; and
a heat dissipating device disposed in the flow channel and on the heat source, the heat dissipating device comprising:
a first fin set disposed at an entrance of the flow channel and comprising a plurality of first fins;
a second fin set disposed at an exit of the flow channel and comprising a plurality of second fins, wherein a part of the second fins are disposed at positions corresponding to a part of the first fins; and
a baffle disposed between the first fin set and the second fin set to divide the flow channel into a first flow channel and a second flow channel parallel to each other,
wherein an entrance of the first flow channel has a sectional area larger than that of an exit of the first flow channel, and an entrance of the second flow channel has a sectional area smaller than that of an exit of the second flow channel.

6. The heat dissipating system of claim 5, wherein the first fins have a height the same as that of the second fins.

7. The heat dissipating system of claim 5, wherein the entrances and the exits of the first flow channel and the second flow channel are determined by a direction of an air flow in the flow channel.

8. The heat dissipating system of claim 7, wherein the entrance of the first flow channel communicates with the first fin set.

9. The heat dissipating system of claim 7, wherein the exit of the second flow channel communicates with the second fin set.

10. The heat dissipating system of claim 5, wherein a range of the flow channel is defined by a range of an air flow.

11. The heat dissipating system of claim 5, wherein a range of the flow channel is defined by a physical partition.

12. The heat dissipating system of claim 5 further comprising at least one fan to determine a direction of an air flow in the flow channel.

13. A heat dissipating system for dissipating heat from a heat source in an electronic device, the heat dissipating system comprising:
a flow channel disposed on the heat source;
at least one fan to determine a direction of an air flow in the flow channel; and
a heat dissipating device disposed in the flow channel and on the heat source, the heat dissipating device comprising:
a first fin set disposed at an entrance of the flow channel and comprising a plurality of first fins;
a second fin set disposed at an exit of the flow channel and comprising a plurality of second fins, wherein a part of the second fins are disposed at positions corresponding to a part of the first fins; and
a baffle disposed between the first fin set and the second fin set to divide the flow channel into a first flow channel and a second flow channel parallel to each other,
wherein the air flow passes through the heat dissipating device and carries away the heat on the first fin set and the second fin set.

14. The heat dissipating system of claim 13, wherein the first fins have a height the same as that of the second fins.

15. The heat dissipating system of claim 13, wherein an entrance of the first flow channel has a sectional area larger than that of an exit of the first flow channel, and an entrance of the second flow channel has a sectional area smaller than that of an exit of the second flow channel.

16. The heat dissipating system of claim 15, wherein the entrances and the exits of the first flow channel and the second flow channel are determined by the direction of the air flow in the flow channel.

17. The heat dissipating system of claim 16, wherein the entrance of the first flow channel communicates with the first fin set.

18. The heat dissipating system of claim 16, wherein the exit of the second flow channel communicates with the second fin set.

19. The heat dissipating system of claim 13, wherein a range of the flow channel is defined by a range of the air flow.

20. The heat dissipating system of claim 13, wherein a range of the flow channel is defined by a physical partition.
